(19) United States
(12) Patent Application Publication
(10) Pub. No.: US 2024/0364268 A1
(43) Pub. Date: Oct. 31, 2024

(54) DISTRIBUTED POWER MANAGEMENT APPARATUS

(71) Applicant: Qorvo US, Inc., Greensboro, NC (US)

(72) Inventor: Nadim Khlat, Cugnaux (FR)

(21) Appl. No.: 18/766,983

(22) Filed: Jul. 9, 2024

Related U.S. Application Data
(63) Continuation of application No. 17/404,587, filed on Aug. 17, 2021.
(60) Provisional application No. 63/151,257, filed on Feb. 19, 2021.

(51) Int. Cl. H03F 1/02; H03F 3/195; H03F 3/24

(52) U.S. Cl. CPC H03F 1/0222; H03F 3/195; H03F 3/245; H03F 2200/102; H03F 2200/451

(57) ABSTRACT

A distributed power management apparatus is provided. The distributed power management apparatus includes an envelope tracking (ET) integrated circuit (ETIC) and a distributed ETIC separated from the ETIC. The ETIC is configured to generate a number of ET voltages for a number of power amplifier circuits and the distributed ETIC is configured to generate a distributed ET voltage(s) for a distributed power amplifier circuit(s). In a non-limiting example, the number of power amplifier circuits and the distributed power amplifier circuit(s) can be disposed on opposite sides (e.g., top and bottom) of a wireless device. As such, in embodiments disclosed herein, the ETIC is provided closer to the power amplifier circuits and the distributed ETIC is provided closer to the distributed power amplifier circuit(s). By providing the ETIC and the distributed ETIC closer to the respective power amplifier circuits, it is possible to reduce trace inductance and unwanted signal distortion.

### RELATED APPLICATIONS

This application is a continuation of U.S. patent application Ser. No. 17/404,587, filed Aug. 17, 2021, which claims the benefit of provisional patent application Ser. No. 63/151,257, filed Feb. 19, 2021, the disclosures of which are hereby incorporated herein by reference in their entireties.

### FIELD OF THE DISCLOSURE

The technology of the disclosure relates generally to a distributed power management apparatus.

### BACKGROUND

Mobile communication devices have become increasingly common in current society for providing wireless communication services. The prevalence of these mobile communication devices is driven in part by the many functions that are now enabled on such devices. Increased processing capabilities in such devices means that mobile communication devices have evolved from being pure communication tools into sophisticated mobile multimedia centers that enable enhanced user experiences.

The redefined user experience requires higher data rates offered by wireless communication technologies, such as fifth-generation new-radio (5G-NR) technology configured to communicate a millimeter wave (mmWave) radio frequency (RF) signal(s) in an mmWave spectrum located above 12 GHZ frequency. To achieve higher data rates, a mobile communication device may employ a power amplifier(s) to increase output power of the mmWave RF signal(s) (e.g., maintaining sufficient energy per bit). However, the increased output power of mmWave RF signal(s) can lead to increased power consumption and thermal dissipation in the mobile communication device, thus compromising overall performance and user experience.

Envelope tracking (ET) is a power management technology designed to improve efficiency levels of power amplifiers to help reduce power consumption and thermal dissipation in mobile communication devices. In an ET system, a power amplifier(s) amplifies an RF signal(s) based on a time-variant ET voltage(s) generated in accordance with time-variant amplitudes of the RF signal(s). More specifically, the time-variant ET voltage(s) corresponds to a time-variant voltage envelope(s) that tracks (e.g., rises and falls) a time-variant power envelope(s) of the RF signal(s). Understandably, the better the time-variant voltage envelope(s) tracks the time-variant power envelope(s), the higher linearity the power amplifier(s) can achieve.

However, the time-variant ET voltage(s) can be highly susceptible to distortions caused by trace inductance, particularly when the time-variant ET voltage(s) is so generated to track the time-variant power envelope(s) of a high modulation bandwidth (e.g., >200 MHZ) RF signal(s). As a result, the time-variant voltage envelope(s) may become misaligned with the time-variant power envelope(s) of the RF signal(s), thus causing unwanted distortions (e.g., amplitude clipping) in the RF signal(s). In this regard, it may be necessary to ensure that the ET power amplifier(s) can consistently operate at a desired linearity for any given instantaneous power requirement of the RF signal(s).

### SUMMARY

Embodiments of the disclosure relate to a distributed power management apparatus. The distributed power management apparatus includes an envelope tracking (ET) integrated circuit (ETIC) and a distributed ETIC separated from the ETIC. The ETIC is configured to generate a number of ET voltages for a number of power amplifier circuits and the distributed ETIC is configured to generate a distributed ET voltage(s) for a distributed power amplifier circuit(s). In a non-limiting example, the number of power amplifier circuits and the distributed power amplifier circuit(s) can be disposed on opposite sides (e.g., top and bottom) of a wireless device. As such, in embodiments disclosed herein, the ETIC is provided closer to the power amplifier circuits and the distributed ETIC is provided closer to the distributed power amplifier circuit(s). By providing the ETIC and the distributed ETIC closer to the respective power amplifier circuits, it is possible to reduce trace inductance and unwanted signal distortion.

In one aspect, a distributed power management apparatus is provided. The distributed power management apparatus includes a distributed ETIC. The distributed ETIC includes a distributed voltage circuit. The distributed voltage circuit is configured to generate a distributed ET voltage based on a distributed ET target voltage. The distributed power management apparatus also includes an ETIC separated from the distributed ETIC. The ETIC includes a number of voltage circuits each configured to generate a respective one of a number of ET voltages and a respective one of a number of low-frequency currents based on a respective one of a number of ET target voltages. The ETIC also includes a control circuit. The control circuit is configured to couple a selected one of the number of voltage circuits to the distributed ETIC to provide the respective one of the number of low-frequency currents to the distributed ETIC. The control circuit is also configured to cause a selected one of the number of ET target voltages to be provided to the distributed ETIC as the distributed ET target voltage.

In another aspect, a wireless device is provided. The wireless device includes a distributed power management apparatus. The distributed ETIC includes a distributed voltage circuit. The distributed voltage circuit is configured to generate a distributed ET voltage based on a distributed ET target voltage. The distributed power management apparatus also includes an ETIC separated from the distributed ETIC. The ETIC includes a number of voltage circuits each configured to generate a respective one of a number of ET voltages and a respective one of a number of low-frequency currents based on a respective one of a number of ET target voltages. The ETIC also includes a control circuit. The control circuit is configured to couple a selected one of the number of voltage circuits to the distributed ETIC to provide the respective one of the number of low-frequency currents to the distributed ETIC. The control circuit is also configured to cause a selected one of the number of ET target voltages to be provided to the distributed ETIC as the distributed ET target voltage. The wireless device also includes one or more power amplifier circuits coupled to the ETIC. The wireless device also includes at least one distributed power amplifier circuit coupled to the distributed ETIC.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a schematic diagram of an exemplary distributed power management apparatus configured according to an embodiment of the present disclosure;

FIG. 2A is a schematic diagram providing an exemplary illustration of an output switch circuit in an envelope tracking (ET) integrated circuit (ETIC) of the distributed power management apparatus of FIG. 1;

FIG. 2B is a schematic diagram providing an exemplary illustration of an input switch circuit in the ETIC of the distributed power management apparatus of FIG. 1;

FIG. 3A is a schematic diagram providing an exemplary illustration of a voltage circuit in the ETIC of the distributed power management apparatus of FIG. 1;

FIG. 3B is a schematic diagram providing an exemplary illustration of a distributed voltage circuit in a distributed ETIC of the distributed power management apparatus of FIG. 1; and

FIG. 4 is a schematic diagram of a wireless device incorporating the distributed power management apparatus of FIG. 1.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments of the disclosure relate to a distributed power management apparatus. The distributed power management apparatus includes an envelope tracking (ET) integrated circuit (ETIC) and a distributed ETIC separated from the ETIC. The ETIC is configured to generate a number of ET voltages for a number of power amplifier circuits and the distributed ETIC is configured to generate a distributed ET voltage(s) for a distributed power amplifier circuit(s). In a non-limiting example, the number of power amplifier circuits and the distributed power amplifier circuit(s) can be disposed on opposite sides (e.g., top and bottom) of a wireless device. As such, in embodiments disclosed herein, the ETIC is provided closer to the power amplifier circuits and the distributed ETIC is provided closer to the distributed power amplifier circuit(s). By providing the ETIC and the distributed ETIC closer to the respective power amplifier circuits, it is possible to reduce trace inductance and unwanted signal distortion.

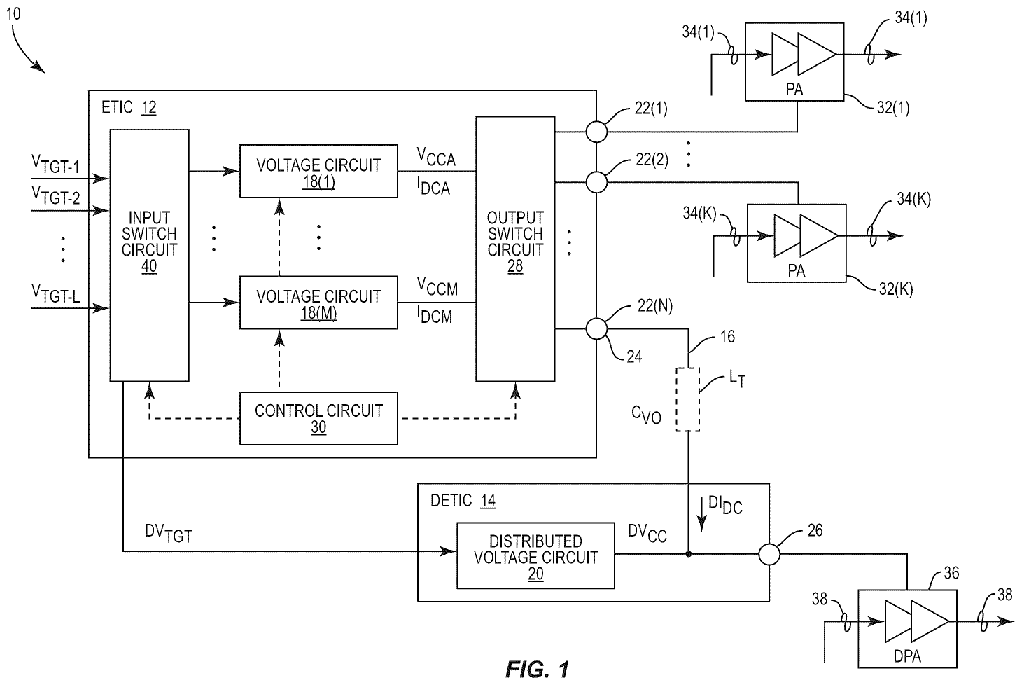

FIG. 1 is a schematic diagram of an exemplary distributed power management apparatus 10 configured according to an embodiment of the present disclosure. The distributed power management apparatus 10 includes an ETIC 12 and a distributed ETIC 14 (denoted as “DETIC”). Notably, the ETIC 12 and the distributed ETIC 14 are separate circuits that are coupled by a conductive trace 16.

The ETIC 12 includes a number of voltage circuits 18(1)-18(M). Each of the voltage circuits 18(1)-18(M) can be configured to generate a respective one of a number of ET voltages V_{CCA}-V_{CCM} and a respective one of a number of low-frequency currents I_{DCA}-I_{DCM} (e.g., direct currents) based on a respective one of a number of ET target voltages V_{TGT-1}-V_{TGT-L}.

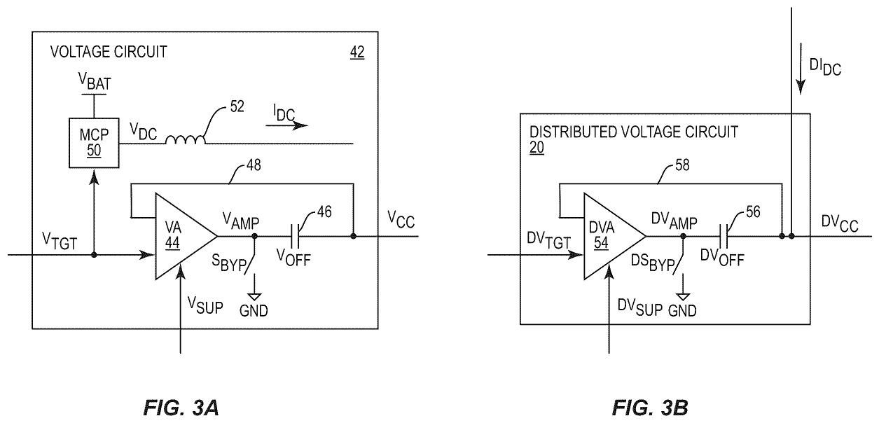

The distributed ETIC 14 includes at least one distributed voltage circuit 20, which is configured to generate at least one distributed ET voltage D_{VCC} based on at least one distributed ET target voltage D_{VTGT}. Notably, the distributed voltage circuit 20 does not generate its own low-frequency current. Instead, the distributed ETIC 14 is configured to receive a respective one of the low-frequency currents I_{DCA}-I_{DCM} generated by a selected one of the voltage circuits 18(1)-18(M) (also referred to as “a selected low-frequency current DI_{DC}” hereinafter) via the conductive trace 16. Further, the distributed ETIC 14 also receives a respective one of the ET target voltages V_{TGT-1}-V_{TGT-L} of the selected one of the voltage circuits 18(1)-18(M) as the distributed ET target voltage D_{VTGT}. As discussed later in FIGS. 3A and 3B, the distributed ETIC 14 can have a smaller footprint than the ETIC 12 by receiving the distributed ET target voltage D_{VTGT} and the selected low-frequency current DI_{DC} from the ETIC 12.

The ETIC 12 can include a number of voltage outputs 22(1)-22(N). In embodiments disclosed herein, N may be smaller than, equal to, or larger than M. One of the voltage outputs 22(1)-22(N) (referred to as “a dedicated voltage output 24” hereinafter) is dedicated to providing the selected low-frequency current DI_{DC} to a distributed voltage output 26 in the distributed ETIC 14. As a non-limiting example, the voltage output 22(N) is discussed hereinafter as the dedicated voltage output 24. However, it should be appreciated that any of the voltage outputs 22(1)-22(N) can be configured to function as the dedicated voltage output 24.

The ETIC 12 further includes an output switch circuit 28 configured to couple any of the voltage circuits 18(1)-18(M) to any of the voltage outputs 22(1)-22(N). The ETIC 12 further includes a control circuit 30, which can be a field-programmable gate array (FPGA), as an example. The control circuit 30 may control the output switch circuit 28 to couple any of the voltage circuits 18(1)-18(M) to the dedicated voltage output 24 to provide the respective one of the low-frequency currents I_{DCA}-I_{DCM} to the distributed voltage output 26 as the selected low-frequency current DI_{DC}.

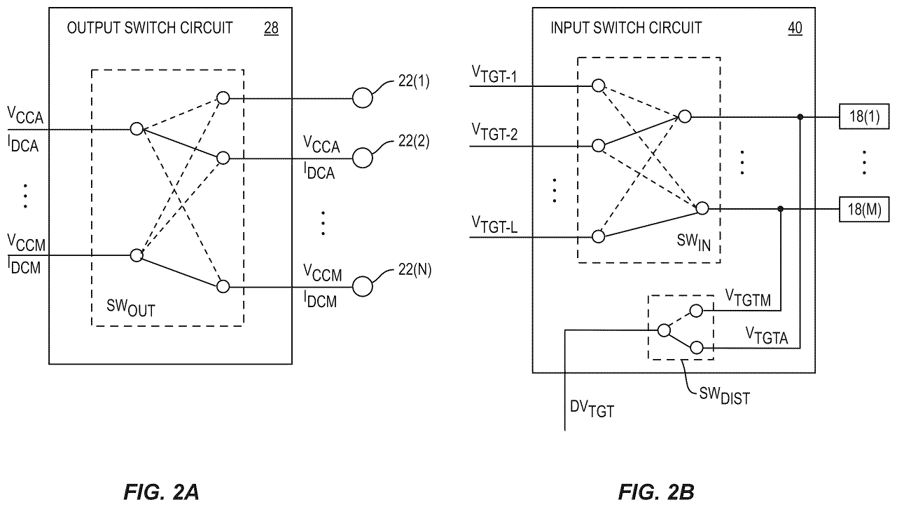

FIG. 2A is a schematic diagram providing an exemplary illustration of the output switch circuit 28 in the ETIC 12 of the distributed power management apparatus 10 of FIG. 2. Common elements between FIGS. 1 and 2A are shown therein with common element numbers and will not be re-described herein.

Notably, the output switch circuit 28 can include one or more output switches SW_{OUT}, which can be any types of switches. For example, the output switches SW_{OUT} can be a multi-pole multi-throw (MPMT) switch or a number of single-pole multi-throw (SPMT) switches. Accordingly, the control circuit 30 can control the output switches SW_{OUT} to selectively couple any of the voltage circuits 18(1)-18(M) to any of the voltage outputs 22(1)-22(N).

With reference back to FIG. 1, the distributed power management apparatus 10 can include one or more power amplifier circuits 32(1)-32(K)(K<N), each configured to amplify a respective one of one or more radio frequency (RF) signals 34(1)-34(K). The control circuit 30 can control the output switch circuit 38 to provide any of the ET voltages V_{CCA}-V_{CCM} and any of the low-frequency currents I_{DCA}-I_{DCM} to any of the power amplifier circuits 32(1)-32(K). The distributed power management apparatus 10 also includes at least one distributed power amplifier circuit 36 configured to amplify at least one distributed RF signal 38. The distributed power amplifier circuit 36 is coupled to the distributed voltage output 26 to receive the distributed ET voltage DV_{CC}.

Since the distributed ETIC 14 is coupled to the ETIC 12 via the conductive trace 16, the distributed ETIC 14 will see a trace inductance L_{T} and a capacitance C_{VO}. Herein, the trace inductance LT represents an equivalent inductance of the conductive trace 16 and the capacitance C_{VO} represents an equivalent capacitance of all active and passive circuits that are coupled to the dedicated voltage output 24. For example, the capacitance C_{VO} can include an equivalent capacitance of a switch (not shown) in the output switch circuit 38 that couples the selected one of the voltage circuits 18(1)-18(M) to the dedicated voltage output 24. In addition, if any of the power amplifier circuits 32(1)-32(K) is coupled to the dedicated voltage output 24, the capacitance C_{VO} would also include an equivalent capacitance of the power amplifier circuit. Given that the equivalent capacitances of the switch and the power amplifier circuit are all parallel capacitances with respect to the dedicated voltage output 24, the capacitance C_{VO} at the dedicated voltage output 24 will equal a sum of the equivalent capacitances of any switch and any power amplifier circuit coupled to the dedicated voltage output 24.

The trace inductance L_{T} and the capacitance C_{VO} can cause an equivalent series resonance frequency f_{RESONANCE} as shown in the equation (Eq. 1) below.

$${f}_{RESONANCE} = 1 / ( 2 π \sqrt{{L}_{T} * Cov} ) \qquad ( Eq . 1 )$$

The equivalent series resonance frequency f_{RESONANCE} can cause linearity degradation in the distributed power amplifier circuit 36 if the equivalent series resonance frequency f_{RESONANCE} is close enough to a modulation bandwidth of the distributed RF signal 38. In this regard, it is necessary to separate the equivalent series resonance frequency f_{RESONANCE} from the modulation bandwidth as much as possible.

In an embodiment, it is possible to separate the equivalent series resonance frequency f_{RESONANCE} from the modulation bandwidth of the distributed RF signal 38 by increasing the equivalent series resonance frequency f_{RESONANCE}. According to the equation (Eq. 1), one way to increase the equivalent series resonance frequency f_{RESONANCE} is to reduce the capacitance C_{VO}. As mentioned above, the capacitance C_{VO} is equal to the sum of equivalent capacitance of any switch and any power amplifier circuit coupled to the dedicated voltage output 24. In a non-limiting example, it is possible to reduce the capacitance C_{VO} by eliminating the equivalent capacitance of any power amplifier circuit coupled to the dedicated voltage output 24. In this regard, the distributed power management apparatus 10 can be configured not to couple any of the power amplifier circuit 32(1)-32(K) to the dedicated voltage output 24. In other words, the power amplifier circuit 32(1)-32(K) can be couped to any of the voltage outputs 22(1)-22(N), except for the dedicated voltage output 24.

The ETIC 12 also includes an input switch circuit 40. The input switch circuit 40 is coupled to a transceiver circuit (not shown) to receive the ET target voltages V_{TGT-1}-V_{TGT-L}. The input switch circuit 40 is also coupled to the voltage circuits 18(1)-18(M) in the ETIC 12 and the distributed voltage circuit 20 in the distributed ETIC 14.

FIG. 2B is a schematic diagram providing an exemplary illustration of the input switch circuit 40 in the ETIC 12 of the distributed power management apparatus 10 of FIG. 2. Common elements between FIGS. 1 and 2B are shown therein with common element numbers and will not be re-described herein.

Notably, the input switch circuit 40 can include one or more input switches SW_{IN}, which can be any type of switches. For example, the input switches SW_{IN} can be an MPMT switch or a number of SPMT switches. Accordingly, the control circuit 30 can control the input switches SW_{IN} to provide any of the ET target voltages V_{TGT-1}-V_{IGT-L} to any of the voltage circuits 18(1)-19(M). The input switch circuit 40 also includes at least one distribution switch SW_{DIST}, which can be a multi-pole single throw (MPST) or a SPMT switch, as an example. The control circuit 30 can control the distribution switch SW_{DIST} to provide any of the ET target voltages V_{TGT-1}-V_{IGT-L} to the distributed voltage circuit 20 as the distributed ET target voltage DV_{TGT}.

With reference back to FIG. 1, as discussed earlier, each of the voltage circuits 18(1)-18(M) in the ETIC 12 can generate the respective one of the ET voltages V_{CCA}-V_{CCM} and the respective one of the low-frequency currents I_{DCA}-I_{DCM}. In this regard, FIG. 3A is a schematic diagram providing an exemplary illustration of a voltage circuit 42, which can be provided in the distributed power management apparatus 10 of FIG. 1 as any of the voltage circuits 18(1)-18(N). Common elements between FIGS. 1 and 3A are shown therein with common element numbers and will not be re-described herein.

The voltage circuit 42 includes a voltage amplifier 44 (denoted as “VA”) coupled in series to an offset capacitor 46. The voltage amplifier 44 is configured to generate an initial ET voltage V_{AMP} based on an ET target voltage V_{TGT}, which can be any of the ET target voltages V_{TGT-1}-V_{TGT-L}. The offset capacitor 46 can be charged by a low-frequency current I_{DC}, which can be any of the low-frequency currents I_{DCA}-I_{DCM}, to an offset voltage VOFF to thereby raise the initial ET voltage V_{AMP} by the offset voltage VOFF. Accordingly, the voltage circuit 42 can generate an ET voltage V_{CC}, which can be any of the ET voltages V_{CCA}-V_{CCM}, that equals a sum of the initial ET voltage V_{AMP} and the offset voltage V_{OFF} (V_{CC}=V_{AMP}+V_{OFF}).

The voltage circuit 42 also includes a bypass switch S_{BYP} having one end coupled in between the voltage amplifier 44 and the offset capacitor 46, and another end to a ground (GND). The bypass switch S_{BYP} is closed while the offset capacitor 46 is being charged toward the offset voltage V_{OFF} and opened when the offset capacitor 46 is charged to the offset voltage V_{OFF}. The voltage circuit 42 also includes a feedback loop 48 that feeds a copy of the ET voltage V_{CC} back to the voltage amplifier 44. The voltage amplifier 44 operates based on a supply voltage V_{SUP}, which may be provided by, for example, the control circuit in the ETIC 12. Notably, the supply voltage V_{SUP} may also be provided by a dedicated supply voltage circuit (not shown) in the ETIC 12.

The voltage circuit 42 also includes a multi-level charge pump (MCP) 50 coupled in series to a power inductor 52. The MCP 50 is configured to generate the low-frequency voltage V_{DC} at multiple levels based on a battery voltage V_{BAT}. In a non-limiting example, the MCP 50 can generate the low-frequency voltage at different levels (e.g., 0 V, V_{BAT}, or 2*V_{BAT}) in accordance with the ET target voltage V_{TGT}. The power inductor 52 induces the low-frequency current I_{DC} based on the low-frequency voltage VDC.

With reference back to FIG. 1, as discussed earlier, the distributed voltage circuit 20 in the distributed ETIC 14 can generate the distributed ET voltage DV_{CC} based on the distributed ET target voltage DV_{TGT}. In this regard, FIG. 3B is a schematic diagram providing an exemplary illustration of the distributed voltage circuit 20 in the distributed power management apparatus 10 of FIG. 1. Common elements between FIGS. 1 and 3B are shown therein with common element numbers and will not be re-described herein.

The distributed voltage circuit 20 includes a distributed voltage amplifier 54 (denoted as “DVA”) coupled in series to a distributed offset capacitor 56. The distributed voltage amplifier 54 is configured to generate a distributed initial ET voltage DV_{AMP} based on the distributed ET target voltage DV_{TGT}, which can be any of the ET target voltages V_{TGT-1}-V_{TGT-L}. The distributed offset capacitor 56 can be charged by the selected low-frequency current DI_{DC}, which can be any of the low-frequency currents I_{DCA}-I_{DCM}, to a distributed offset voltage DV_{OFF} to thereby raise the distributed initial ET voltage DV_{AMP} by the distributed offset voltage DV_{OFF}. Accordingly, the distributed voltage circuit 20 can generate the distributed ET voltage DV_{CC} that equals a sum of the distributed initial ET voltage DV_{AMP} and the distributed offset voltage DV_{OFF} (DV_{CC}=DV_{AMP}+DV_{OFF}).

The distributed voltage circuit 20 also includes a distributed bypass switch DS_{BYP} having one end coupled in between the distributed voltage amplifier 54 and the distributed offset capacitor 56, and another end to the GND. The distributed bypass switch DS_{BYP} is closed while the distributed offset capacitor 56 is being charged toward the distributed offset voltage DV_{OFF} and opened when the distributed offset capacitor 56 is charged to the distributed offset voltage DV_{OFF}. The voltage circuit 42 also includes a distributed feedback loop 58 that feeds a copy of the distributed ET voltage DV_{CC} back to the distributed voltage amplifier 54. The distributed voltage amplifier 54 operates based on a distributed supply voltage DV_{SUP}, which may be provided by, for example, the control circuit in the ETIC 12. Notably, the distributed supply voltage DV_{SUP} may also be provided by a dedicated supply voltage circuit (not shown) in the ETIC 12 or in the distributed ETIC 14.

In contrast to the voltage circuit 42 in FIG. 3A, the distributed voltage circuit 20 does not include the MCP 50 and the power inductor 52. Instead, the distributed voltage circuit 20 relies on the MCP 50 and the power inductor 52 in the voltage circuit 42 of FIG. 3A to supply the selected low-frequency current DI_{DC}. By eliminating the MCP 50 and the power inductor 52 from the distributed voltage circuit 20, it is thus possible to reduce footprint of the distributed voltage circuit 20.

With reference back to FIG. 1, when the selected one of the voltage circuits 18(1)-18(M) is coupled to the dedicated voltage output 24 to provide the selected low-frequency current DI_{DC} to the distributed voltage circuit 20, the control circuit 30 can deactivate the voltage amplifier 44 in the selected one of the voltage circuits 18(1)-18(M). The control circuit 30 can further control the distribution switch SW_{DIST} in the input switch circuit 40 to provide the respective one of the ET target voltages V_{TGT-1}-V_{IGT-L} received by the selected one of the voltage circuits 18(1)-18(M) to the distributed voltage circuit 20 in the distributed ETIC 14. For example, if the voltage circuit 18(1) has been coupled to the dedicated voltage output 24 and is configured to receive the ET target voltage V_{TGT-1}, the control circuit 30 would deactivate the voltage amplifier 44 in the voltage circuit 18(1) and control the distribution switch SW DIST to provide the ET target voltage V_{TGT-1} to the distributed voltage circuit 20 as the distributed ET target voltage DV_{TGT}.

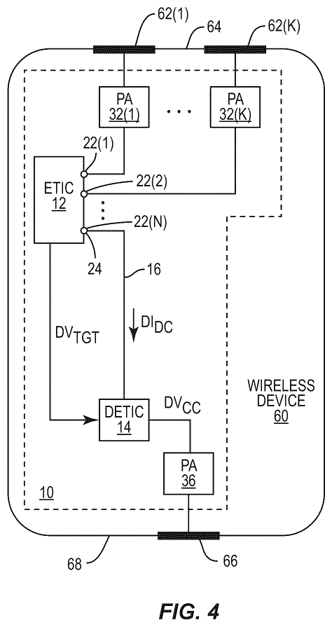

The distributed power management apparatus 10 can be provided in a wireless device to enable a flexible antenna configuration. In this regard, FIG. 4 is a schematic diagram of a wireless device 60 incorporating the distributed power management apparatus 10 of FIG. 1. Common elements between FIGS. 1 and 4 are shown therein with common element numbers and will not be re-described herein.

The wireless device 60 can include one or more antennas 62(1)-62(K) disposed on a first side 64 (e.g., top side) of the wireless device 60. As such, the power amplifier circuits 32(1)-32(K) can each be coupled to a respective one of the antennas 62(1)-62(K).

The wireless device 60 also includes at least one distributed antenna 66 disposed on a second side 68 (e.g., bottom side) of the wireless device 60. As shown in FIG. 4, the second side 68 is an opposite side relative to the first side 64. By disposing the antennas 64 and the distributed antenna 66 on the opposite sides, it is possible to mitigate a so-called hand-blocking effect. Accordingly, the distributed power amplifier circuit 36 can be coupled to the distributed antenna 66.

In embodiments disclosed herein, the ETIC 12 is disposed closer to any of the power amplifier circuits 32(1)-32(K) than to the distributed power amplifier circuit 36. Similarly, the distributed ETIC 14 is disposed closer to the distributed power amplifier circuit 36 than to any of the power amplifier circuits 32(1)-32(K). As a result, it is possible to reduce potential trace inductance distortion in the ET voltages V_{CCA}-V_{CCM} and the distributed ET voltage DV_{CC}.

Those skilled in the art will recognize improvements and modifications to the preferred embodiments of the present disclosure. All such improvements and modifications are considered within the scope of the concepts disclosed herein and the claims that follow.

What is claimed is:

1. A method for operating a distributed power management apparatus comprising:
generating, from a distributed envelope tracking (ET) integrated circuit (ETIC), a distributed ET voltage based on a distributed ET target voltage;
generating, from each of a plurality of voltage circuits in an ETIC separated from the distributed ETIC, a respective one of a plurality of ET voltages and a respective one of a plurality of low-frequency currents based on a respective one of a plurality of ET target voltages;
coupling a selected one of the plurality of voltage circuits to the distributed ETIC to provide the respective one of the plurality of low-frequency currents to the distributed ETIC; and
providing a selected one of the plurality of ET target voltages to the distributed ETIC as the distributed ET target voltage.

2. The method of claim 1, wherein generating the distributed ET voltage comprises:
generating a distributed initial ET voltage based on the distributed ET target voltage; and
raising the distributed initial ET voltage by a distributed offset voltage to generate the distributed ET voltage.

3. The method of claim 1, wherein generating the respective one of the plurality of ET voltages and the respective one of the plurality of low-frequency currents comprises:
generating a low-frequency voltage based on a battery voltage;
inducing the respective one of the plurality of low-frequency currents based on the low-frequency voltage;
generating an initial ET voltage based on the respective one of the plurality of ET target voltages; and
raising the initial ET voltage by an offset voltage to generate the respective one of the plurality of ET voltages.

4. The method of claim 3, further comprising generating the low-frequency voltage in the selected one of the plurality of voltage circuits based on the selected one of the plurality of ET target voltages.

5. The method of claim 4, further comprising causing the selected one of the plurality of voltage circuits not to generate the initial ET voltage.

6. The method of claim 1, further comprising:
receiving, via an input switch circuit in the ETIC, the plurality of ET target voltages from a transceiver circuit; and
controlling the input switch circuit to couple any of the plurality of ET target voltages to any of the plurality of voltage circuits.

7. The method of claim 6, further comprising controlling the input switch circuit to cause the selected one of the plurality of ET target voltages to be provided to the distributed ETIC and the selected one of the plurality of voltage circuits.

8. The method of claim 1, further comprising controlling an output switch circuit in the ETIC to couple any of the plurality of voltage circuits to any of a plurality of voltage outputs in the ETIC.

9. The method of claim 8, further comprising:
coupling the distributed ETIC to the ETIC via a selected one of the plurality of voltage outputs; and
controlling the output switch circuit to couple the selected one of the plurality of voltage circuits to the selected one of the plurality of voltage outputs to provide the respective one of the plurality of low-frequency currents to the distributed ETIC.

10. The method of claim 9, further comprising:
coupling each of one or more power amplifier circuits to a respective one of the plurality of voltage outputs that is different from the selected one of the plurality of voltage outputs coupled to the distributed ETIC; and
coupling at least one distributed power amplifier circuit to the distributed ETIC.

11. A method for operating a distributed power management apparatus in a wireless device comprising:
generating, from a distributed envelope tracking (ET) integrated circuit (ETIC) in the distributed power management apparatus, a distributed ET voltage based on a distributed ET target voltage;
generating, from each of a plurality of voltage circuits in an ETIC separated from the distributed ETIC in the distributed power management apparatus, a respective one of a plurality of ET voltages and a respective one of a plurality of low-frequency currents based on a respective one of a plurality of ET target voltages;
coupling a selected one of the plurality of voltage circuits to the distributed ETIC to provide the respective one of the plurality of low-frequency currents to the distributed ETIC;
providing a selected one of the plurality of ET target voltages to the distributed ETIC as the distributed ET target voltage;
coupling the ETIC to one or more power amplifier circuits in the wireless device; and
coupling at least one distributed power amplifier circuit to the distributed ETIC.

12. The method of claim 11, further comprising:
providing one or more antennas along one side of the wireless device and coupling each of the one or more antennas to a respective one of the one or more power amplifier circuits; and
providing at least one distributed antenna along an opposite side of the wireless device and coupling the at least one distributed antenna to the at least one distributed power amplifier circuit.

13. The method of claim 11, further comprising:
disposing the ETIC closer to any of the one or more power amplifier circuits than to the at least one distributed power amplifier circuit; and
disposing the distributed ETIC closer to the at least one distributed power amplifier circuit than to any of the one or more power amplifier circuits.

14. The method of claim 11, wherein generating the distributed ET voltage comprises:
generating a distributed initial ET voltage based on the distributed ET target voltage; and
raising the distributed initial ET voltage by a distributed offset voltage to generate the distributed ET voltage.

15. The method of claim 11, wherein generating the respective one of the plurality of ET voltages and the respective one of the plurality of low-frequency currents comprises:
generating a low-frequency voltage based on a battery voltage;
inducing the respective one of the plurality of low-frequency currents based on the low-frequency voltage;
generating an initial ET voltage based on the respective one of the plurality of ET target voltages; and
raising the initial ET voltage by an offset voltage to generate the respective one of the plurality of ET voltages.

16. The method of claim 15, further comprising:
generating the low-frequency voltage in the selected one of the plurality of voltage circuits based on the selected one of the plurality of ET target voltages; and
causing the selected one of the plurality of voltage circuits not to generate the initial ET voltage.

17. The method of claim 11, further comprising
receiving, via an input switch circuit in the ETIC, the plurality of ET target voltages from a transceiver circuit; and
controlling the input switch circuit to couple any of the plurality of ET target voltages to any of the plurality of voltage circuits.

18. The method of claim 17, further comprising controlling the input switch circuit to cause the selected one of the plurality of ET target voltages to be provided to the distributed ETIC and the selected one of the plurality of voltage circuits.

19. The method of claim 11, further comprising controlling an output switch circuit in the ETIC to couple any of the plurality of voltage circuits to any of a plurality of voltage outputs in the ETIC.

20. The method of claim 19, further comprising:
coupling each of one or more power amplifier circuits to a respective one of the plurality of voltage outputs that is different from the selected one of the plurality of voltage outputs coupled to the distributed ETIC; and
coupling the at least one distributed power amplifier circuit to the distributed ETIC.
